(19) United States
(12) Patent Application Publication
(10) Pub. No.: US 2026/0349024 A1
(43) Pub. Date: Nov. 5, 2026

(54) SYSTEMS AND METHODS FOR SIMULTANEOUSLY AND ASYNCHRONOUSLY TESTING A PLURALITY OF CONSUMER ELECTRONIC DEVICES

(71) Applicant: Contec, LLC, Schenectady, NY (US)

(72) Inventors: Rajeev Tiwari, San Jose, CA (US); Rafael Alberto Villanueva, Clifton Park, NY (US)

(21) Appl. No.: 19/195,440

(22) Filed: Apr. 30, 2025

(51) Int. Cl. G01R 31/28

(52) U.S. Cl. CPC G01R 31/2834

(57) ABSTRACT

Technologies are described herein for enabling the automated testing of consumer electronic devices, such as Wi-Fi mesh devices, by providing a suitable test station that includes a plurality of test fixtures for simultaneously and asynchronously testing a plurality of consumer electronic devices. Each test fixture includes features that allow it to interact with the electronic device's inputs, such as buttons, and outputs, such as status LEDs. Each test fixture may be controlled by a test fixture controller that executes test scripts or other routines that reset and determine the functionality of the electronic device as desired.

### TECHNICAL FIELD

This disclosure relates to systems for testing electronic devices. More specifically, this disclosure relates to a test station and test fixtures that can be configured to simultaneously and asynchronously perform comprehensive testing of a plurality of consumer electronic devices.

### BRIEF SUMMARY

The present disclosure relates to technologies for testing the functionality of consumer electronic devices of the type commonly provided to consumers by Internet Service Providers (“ISPs”). According to some embodiments, test fixtures for testing consumer electronic devices can include a plurality of features that allow the test fixtures to be used in conjunction with an automated test station for resetting devices to factory settings and for testing a variety of functions associated with the electronic devices.

According to further embodiments, a test fixture comprises a test jig with features that allow an electronic device to be precisely positioned and held in place in the test jig during a testing process. The test jig further comprises one of more actuators, such as linear motors or solenoids, that are aligned with buttons on the electronic device and capable of pressing each of the buttons in response to instructions from a controller or computer that is part of the test fixture. The jig further comprises at least one sensor capable of detecting the color of light emitted by one or more status-indicating lights or LEDs on the electronic device.

According to further embodiments, multiple test fixtures can be connected to and controlled by a server or personal computer in order to provide a test station configured to simultaneously and asynchronously test multiple electronic devices and provide an efficient and convenient user interface for a test station operator.

Various implementations described in the present disclosure can comprise additional systems, methods, features, and advantages, which may not necessarily be expressly disclosed herein but will be apparent to one of ordinary skill in the art upon examination of the following detailed description and accompanying drawings. It is intended that all such systems, methods, features, and advantages be included within the present disclosure and protected by the accompanying claims. The features and advantages of such implementations can be realized and obtained by means of the systems, methods, features particularly pointed out in the appended claims. These and other features will become more fully apparent from the following description and appended claims or can be learned by the practice of such exemplary implementations as set forth hereinafter.

### BRIEF DESCRIPTION OF THE DRAWINGS

In the following Detailed Description, references are made to the accompanying drawings, which form a part hereof, and show, by way of illustration, specific embodiments or examples. The features and components of the following figures are illustrated to emphasize the general principles of the present disclosure. The drawings herein are not drawn to scale. Like numerals represent like elements throughout the several figures.

FIG. 1 is a diagram of a test station that comprises a plurality of test fixtures connected to a master controller that controls the testing of electronic devices.

FIG. 2A is a top view of an exemplary electronic device of the type provided by ISPs for use by customers, according to embodiments that are described herein.

FIG. 2B is a rear view of the exemplary electronic device of FIG. 2A and various communication ports, connectors, and other features that can be found on a rear surface of the electronic device.

FIG. 2C is a bottom view of the exemplary electronic device of FIG. 2A and shows a reset button and other features that can be found on the bottom surface of the electronic device.

FIG. 3 is a block diagram of a test fixture that forms a part of the test station of FIG. 1 and is configured to test an electronic device of the type shown in FIGS. 2A, 2B, and 2C.

FIG. 4 is a diagram that illustrates an electronic device of the type shown in FIGS. 2A, 2B, and 2C inserted into the test fixture shown in FIG. 3.

FIG. 5 is a flow chart illustrating a process for using the test station of FIG. 1 to test electronic devices of the type shown in FIGS. 2A, 2B, and 2C.

FIG. 6 is a flow chart illustrating an automated process that can be executed by a test fixture in order to test the functionality of an electronic device.

FIG. 7 is a drawing illustrating features of a screen display that is associated with the test station of FIG. 1 and has a window corresponding to each test fixture associated with the test station.

FIG. 8 is a drawing illustrating features of one of the windows shown on the screen display of FIG. 7.

### DETAILED DESCRIPTION

The present disclosure can be understood more readily by reference to the following detailed description, examples, drawings, and claims, and their previous and following descriptions. However, before the present devices, systems, and/or methods are disclosed and described, it is to be understood that this disclosure is not limited to the specific devices, systems, and/or methods disclosed unless otherwise specified, as such can, of course, vary. It is also to be understood that the terminology used herein is for the purpose of describing particular aspects only and is not intended to be limiting.

The following description is provided as an enabling teaching of the present devices, systems, and/or methods in their best, currently known aspect. To this end, those skilled in the relevant art will recognize and appreciate that many changes can be made to the various aspects described herein, while still obtaining the beneficial results of the present disclosure. It will also be apparent that some of the desired benefits of the present disclosure can be obtained by utilizing some of the features of the present disclosure without utilizing other features. Accordingly, those skilled in the art will recognize that many modifications and adaptations to the present disclosure are possible and can even be desirable in certain circumstances and are a part of the present disclosure. Thus, the following description is provided as illustrative of the principles of the present disclosure and not in limitation thereof.

As used throughout, the singular forms “a,” “an” and “the” include plural referents unless the context clearly dictates otherwise. Thus, for example, reference to a quantity of one of a particular element can comprise two or more such elements unless the context indicates otherwise.

Ranges can be expressed herein as from “about” one particular value, and/or to “about” another particular value. When such a range is expressed, another aspect comprises from the one particular value and/or to the other particular value. Similarly, when values are expressed as approximations, by use of the antecedent “about” or “substantially,” it will be understood that the particular value forms another aspect. It will be further understood that the endpoints of each of the ranges are significant both in relation to the other endpoint, and independently of the other endpoint.

For purposes of the present disclosure, a material property or dimension measuring about X or substantially X on a particular measurement scale measures within a range between X plus an industry-standard upper tolerance for the specified measurement and X minus an industry-standard lower tolerance for the specified measurement. Because tolerances can vary between different materials, processes and between different models, the tolerance for a particular measurement of a particular component can fall within a range of tolerances.

As used herein, the terms “optional” or “optionally” mean that the subsequently described event or circumstance may or may not occur, and that the description comprises instances where said event or circumstance occurs and instances where it does not.

The word “or” as used herein means any one member of a particular list and also comprises any combination of members of that list.

To simplify the description of various elements disclosed herein, the conventions of “top,” “bottom,” “side,” “upper,” “lower,” “horizontal,” and/or “vertical” may be referenced. Unless stated otherwise, “top” describes that side of the system or component that is facing upward, and “bottom” is that side of the system or component that is opposite or distal the top of the system or component and is facing downward. Unless stated otherwise, “side” describes that an end or direction of the system or component facing in horizontal direction. “Horizontal” or “horizontal orientation” describes that which is in a plane aligned with the horizon. “Vertical” or “vertical orientation” describes that which is in a plane that is angled at 90 degrees to the horizontal.

The following detailed description is directed to methods, systems, and technologies for automatically processing (i.e., resetting and testing) consumer electronic devices of the type commonly provided to subscribers by Internet Service Providers (“ISPs”). An ISP may be a telco, Multiple System Operator (“MSO”), or other entity that provides one or more electronic devices, such as a cable modem, DSL modem, Optical Network Terminal (ONT), Gateway, wireless router, or other devices to a subscriber in order to allow the subscriber to communicate with the ISP's network. Those skilled in the art will appreciate that an ISP's network may be a cable network, a fiber network, a satellite network, or other type of network that is used to provide internet, video, VoIP, telephone or other services to subscribers. In some cases, the ISP may also provide Wi-Fi routers, Wi-Fi access points, and Wi-Fi mesh networks to extend Internet access throughout the consumer's home or business via Wi-Fi. These devices are almost always provided to a subscriber with the expectation that these devices will be returned to the ISP at some point in the future. In most cases, these electronic devices are leased to subscribers and remain the property of the ISP. The terms consumer electronic device, electronic device, and device may be used interchangeably herein.

The equipment provided by the ISP to the subscriber may be returned to the ISP for several reasons. In some cases, the equipment fails to work properly and is returned to the ISP when the customer is provided with replacement equipment. In other cases, a subscriber may want to upgrade the equipment to a newer model or to a model that offers different features. Finally, subscriber equipment is returned to the ISP when a subscriber cancels his or her service and no longer needs the equipment.

Unless the returned equipment is outdated or obsolete, the ISP usually will want to reuse the equipment and provide it to other subscribers. In some cases, this may require that the equipment be reset, tested, refurbished, and repaired (if necessary) to ensure that it works properly and is in good condition. The process of resetting an electronic device may include resetting it to its original factory settings or to default settings dictated by the ISP. If the equipment proves to be satisfactory, it will be repackaged and put back into the ISP's inventory so that it may be sent to new subscribers, or to existing subscribers who need a replacement or an upgrade. This reuse of equipment allows the ISP to reduce the amount of new equipment it purchases from its suppliers, thus saving a significant amount of money.

Different types of consumer electronic devices have different combinations of buttons, LED status indicators, communication ports, power ports, and the like. Before a used electronic device may be redeployed to a subscriber by the ISP, it can be reset to factory default settings or other settings dictated by the ISP, tested to ensure that it works properly and inspected to ensure that it does not have cosmetic damage that would render it unsuitable for future use. The process of resetting and testing an electronic device may include applying power to the device, pressing the buttons on the device, and observing or analyzing the resulting changes in the LED status indicators or other outputs.

In order to provide a test station that is capable of quickly, efficiently, and reliably resetting and testing the functionality of consumer electronic devices, embodiments described in the present disclosure feature test fixtures that employ various features to perform the appropriate resetting and testing functions. The test fixtures include a test jig that holds electronic device securely in place so that the buttons on the electronic device are aligned with actuators (e.g., linear motors) that are configured to press the button(s) on the electronic device in response to signals from a controller. The test jigs can include light sensors in order to determine the status of the consumer electronic device and assess its functionality. These features allow a sophisticated electronic device to be reliably reset and tested automatically, quickly, and thoroughly, and its condition to be accurately ascertained in order to determine if it is functioning properly and suitable for reuse. The results of the test are then recorded and documented for purposes of inventory control, etc. Multiple test fixtures can be used as part of a larger test station that allows multiple electronic devices to be tested asynchronously and simultaneously.

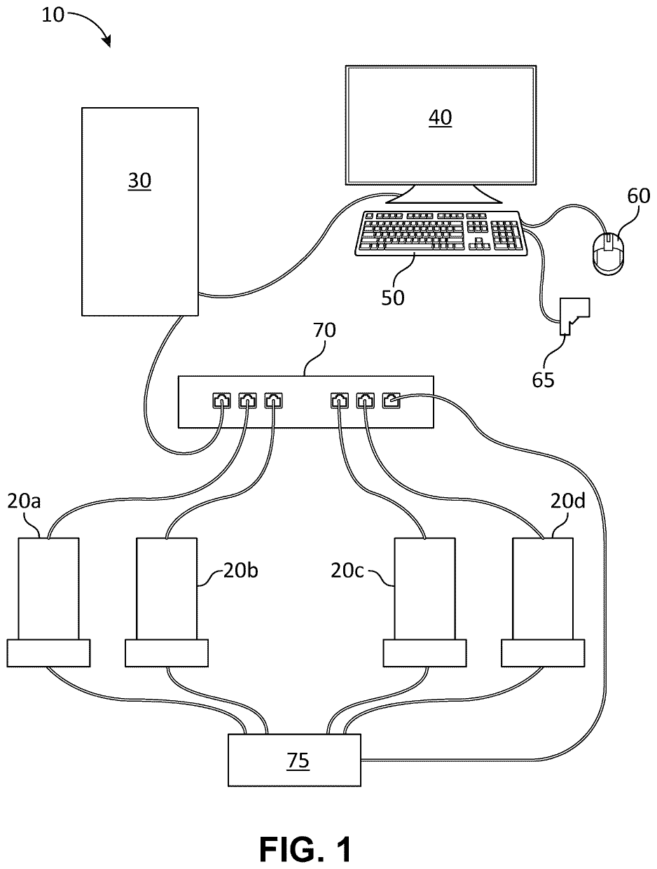

FIG. 1 is a diagram of a test station 10 for simultaneously and asynchronously processing (i.e., resetting, testing, etc.) a plurality of consumer electronic devices (not shown). The test station 10 can include a plurality of test fixtures 20a-d that are connected to a master controller 30 or central computer. The master controller 30 can be connected to user interface devices, such as a display 40, a keyboard 50, and mouse 60, bar code/QR code scanner 65, or other input device. These connections may be wired or wireless. Alternatively, the user interface device (display 40) may include a touch screen, which can eliminate the need for the keyboard 50 and mouse 60. The description that follows describes the use of a touch screen user interface device, though the same input can be provided using a keyboard and mouse or other type of pointing device.

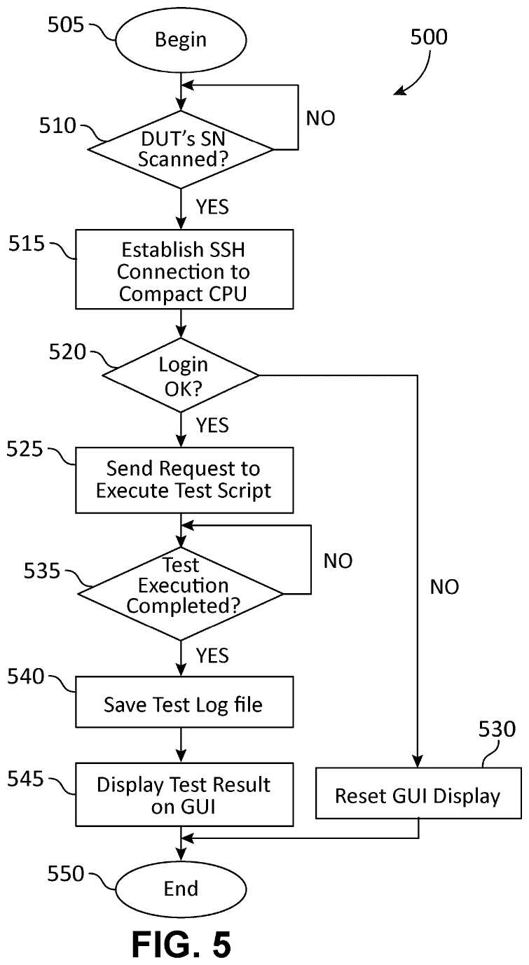

Each of the test fixtures 20a-d may be connected to the master controller 30 using various types of connections, including USB cable, Ethernet cable, Wi-Fi, or other means. In the test station 10 illustrated in FIG. 1, the master controller 30 and the test fixtures 20a-d are connected to an Ethernet switch 70, which allows the various devices to communicate with each other. The master controller 30 can be a personal computer that runs the Windows, MacOS, or Linux operating systems, and can run software that connects to and communicates with each of the test fixtures 20a-d, as further described in conjunction with the process shown in FIG. 5. Those skilled in the art will understand and appreciate that although four test fixtures 20a-d are shown in FIG. 1, a test station in accordance with the present disclosure is not limited to four. A test station that incorporates the features discussed herein can employ virtually any number of test fixtures to simultaneously and asynchronously process any number of consumer electronic devices.

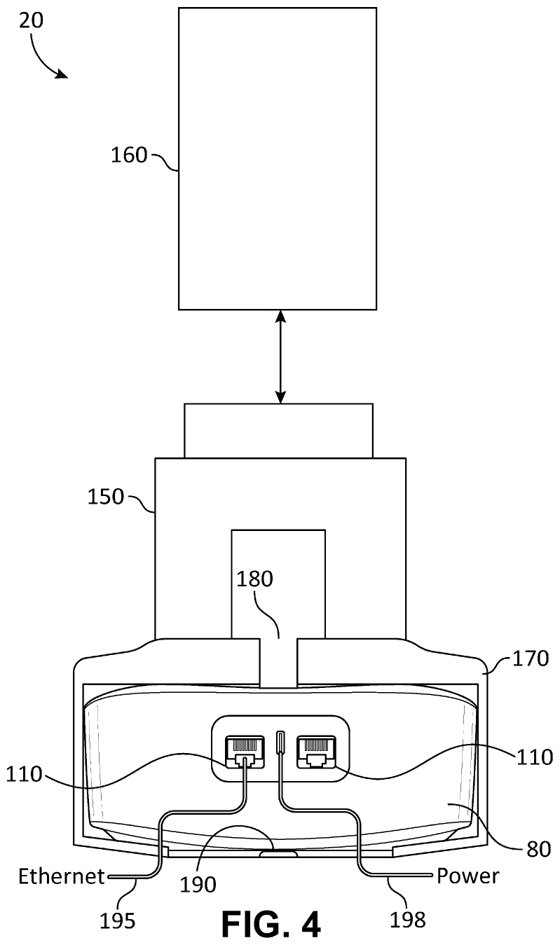

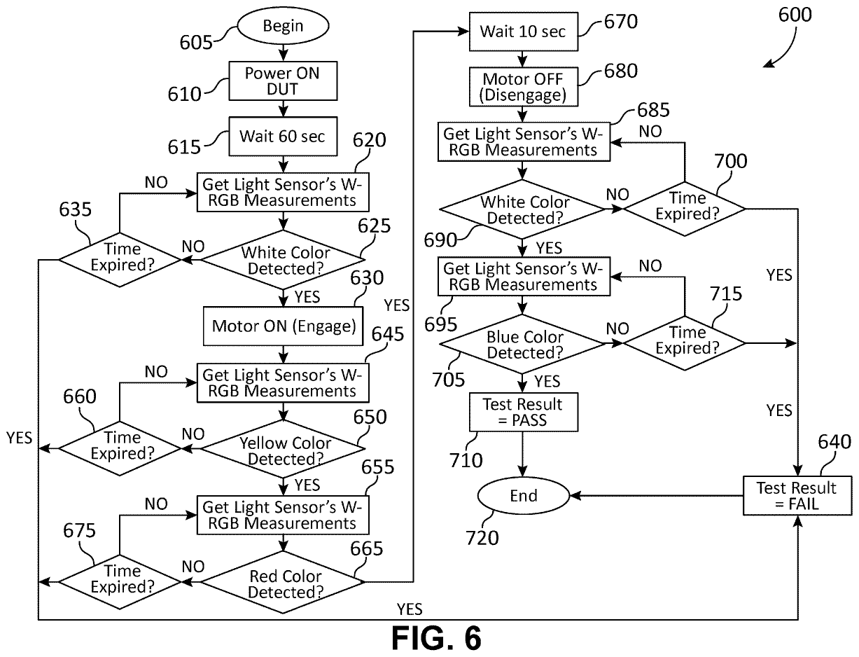

FIG. 1 also illustrates the use of a web power switch 75. A web power switch is a device that allows a person or computer equipment to remotely control the power to connected devices using a web interface. It essentially acts as a smart power strip, enabling an operator or computer to turn the web power switch's power ports on and off. In this case, the web power switch is connected to the Ethernet switch 70 via an Ethernet cable and allows the master controller 30 to control power to the test fixtures 20a-d as described below in connection with FIGS. 4 and 6.

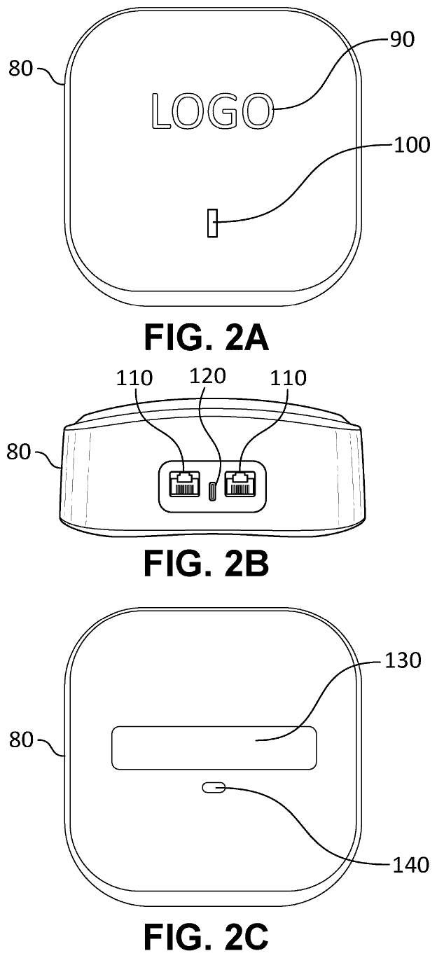

FIGS. 2A, 2B, and 2C illustrate one example of any number of consumer electronic devices that can be reset and tested using the techniques and methods described in conjunction with the test station 10 of FIG. 1. FIGS. 2A, 2B, and 2C illustrate the top, rear, and bottom, respectively, of a device under test (“DUT”) 80. In the instant example, the DUT 80 is a Wi-Fi mesh access point, such as an Eero Pro 6 mesh Wi-Fi router or access point (see https://www.eero.com/shop/eero-pro-6). Those skilled in the art will understand and appreciate that the test station 10 and test fixtures 20 can be designed to accommodate a variety of types of electronic devices, including other Wi-Fi mesh routers/access points and other electronic devices.

FIG. 2A illustrates the features that may be found on the top surface of a DUT 80. These include a logo 90, and a status LED 100. FIG. 2B illustrates the features that may be found on the rear surface of a DUT 80. These include communication ports, such as Ethernet ports 110, and a power port, such as USB-C connector 120. FIG. 2C illustrates the features that may be found on the bottom surface of a DUT 80. These include a label of some sort 130 and a reset button 140. The functions associated with these buttons, connectors and LED status indicators, and how they are used in the process of resetting and testing the DUT 80 will be described in more detail below.

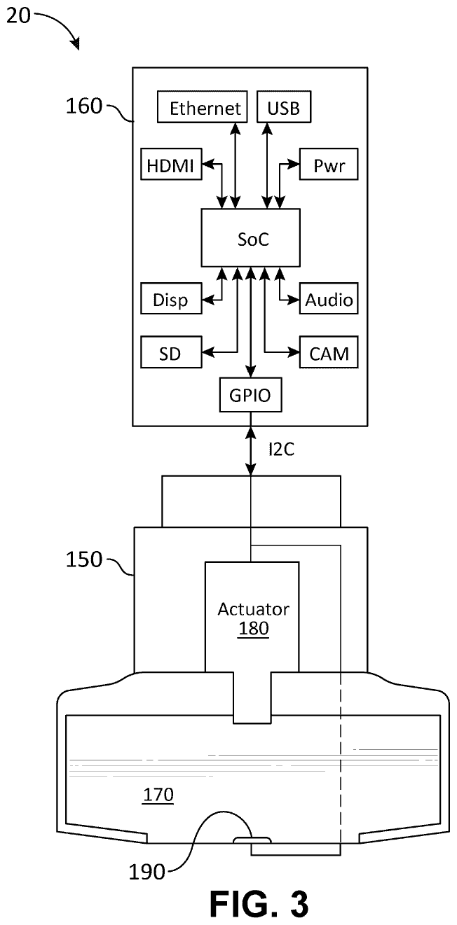

FIG. 3 is a block diagram of a test fixture 20 for testing consumer electronic devices, such as the DUT 80 shown in FIGS. 2A, 2B, and 2C. The test fixture is designed to receive DUT 80 (as illustrated in FIG. 4) and hold it securely in place during the testing process. The test fixture 20 includes a test jig 150 and a test fixture controller 160. The test jig 150 includes a cavity 170, chamber or other enclosure, designed to hold the DUT 80 (not shown in FIG. 3) while it is being reset and tested. The dimensions of the cavity, chamber, or enclosure match the size, shape, and features of the specific consumer electronic devices to be tested. As shown more clearly in FIG. 4, the DUT 80 can be inserted into cavity 170 of the test jig 150 so that the bottom surface of the DUT 80 is facing actuator 180 and the rear surface is facing up.

FIG. 3 shows the placement of an actuator 180 and a light sensor 190 in the interior of the test jig cavity. As will be described in more detail below, the actuator 180 is aligned with the reset button 140 on the bottom of the DUT 80 and the light sensor is aligned with the status LED on the top of the DUT 80. Those skilled in the art will appreciate that an actuator (such as actuator 80) is, generally speaking, a component of a machine that is responsible for moving a mechanism. There are different types of actuators, including electrical, hydraulic, pneumatic, and mechanical. An actuator's motion may be linear or rotational. In the present disclosure, the actuators can be linear motors or electrical, tubular, linear solenoids, which may be easily controlled by appropriate electrical signals from a test fixture controller 160.

The design parameters for the test jig 150 and cavity 170 can depend on the size, shape and features of the consumer electronic devices to be tested. Buttons on electronic devices can come in a variety of sizes, shapes, and locations. Some may be very small. Some may be positioned very close together. Consequently, the arrangement between the test jig and the DUT 80 may be quite precise. If testing an electronic device requires more than one button to be pressed, the test jig 150 will need to include multiple actuators positioned adjacent the buttons. Similarly, if testing an electronic device requires that more than one LED be monitored, the test jig will need to include multiple light sensors positioned adjacent the LEDs. In addition, those skilled in the art will appreciate that electronic devices may include other inputs and outputs that may be accommodated by variations in the design of the test jig 150.

In an embodiment, the light sensors 190 can each be a VEML6040 RGBW Color Sensor with an I2C interface, manufactured by Vishay Intertechnology, Inc., or any other light sensor that is small enough and sensitive enough to operate in this environment. As discussed above, the number and placement of the light sensors may vary depending on the light-related features on the DUT 80 and the need to test those features.

In an embodiment, the actuators 180 can be linear motors mounted perpendicular to the appropriate surface of the cavity 170. The positioning of the linear motors can be such that when the DUT 80 is placed in the test jig, the surface of the linear motors may be in contact with, but not depress, the reset button 140 on the DUT when the linear motors are in their un-actuated or un-energized state. It is possible that some of the buttons on the DUT 80 may be recessed, flush with the surface of the DUT, or at different heights above the surface of the DUT. Thus, the placement and position of the actuators 180 in a test jig will depend on the features of the specific electronic devices to be tested in that test jig. The stroke (i.e., the distance the linear motor travels when energized), force, and timing of the actuator's movement will be determined by the specifications or requirements for the particular buttons on the specific electronic devices that will be tested. For example, in order to reset the DUT, a linear motor must depress the reset button long enough to place the DUT in the reset mode. Depressing it for too short a period of time will not yield the desired result.

Turning briefly to FIG. 4, this block diagram illustrates how a DUT 80 may be positioned in the cavity 170 of the test jig 150. It also shows additional connections to ports on the rear surface of DUT 80. As shown here, the DUT 80 is positioned so that the rear surface is facing up or outward, thus exposing the Ethernet ports 110 and the USB-C connector 120. It will be appreciated that the top surface of the DUT 80 must be facing toward the light sensor 190 and the bottom surface facing toward the actuator 180 in order for the features of the DUT to match up with the features of the test jig.

FIG. 4 also illustrates the connections to the ports on the rear of the DUT 80. In the embodiment described herein, an Ethernet cable 195 connects at least one of the Ethernet ports 110 to the Ethernet switch 70 that is shown in FIG. 1. In addition, a web power switch 75 is connected to the USB-C port 120 via a compatible USB cable 198 in order to provide and control power to the DUT 80.

Refer again to FIG. 3 for a description of the main circuitry and features of a test fixture controller 160 that may be used in the test fixture 20. In order to use the test fixture to perform automated testing on an electronic device, the test fixture can use a test fixture controller 160 and associated circuitry capable of executing a test routine and controlling, manipulating, or communicating with the various features of the DUT 80, with the test jig 150, and with a user or operator via the display 40, keyboard 50, mouse 60, and scanner 65 that are connected to the master controller 30. The test fixture controller 160 can be programmed to execute a process or method that utilizes the features of the test jig 150 to reset the DUT 80 and to test some or all of the functions of the DUT 80.

In one embodiment, the test station controller 160 can be a commercially available single-board computer such as a Raspberry Pi, a microcontroller such as the Arduino line of boards and kits, or a similar device. FIG. 3 includes a block diagram of the common elements of a Raspberry Pi single-board computer. The Raspberry Pi that forms test fixture controller 160 is a credit card sized computer that can be plugged into a monitor. It can be configured as a minicomputer by connecting a keyboard, mouse, and display to the Raspberry Pi. Raspberry Pi has an ARM processor and a sufficient amount of RAM (e.g., 512 MB of RAM).

What follows is a general description of the Raspberry Pi architecture and the features associated with the Raspberry Pi device. These features as illustrated in the block diagram of test fixture controller 160 in FIG. 3.

Processor: Raspberry Pi uses Broadcom BCM2835 system on chip (SoC) which is an ARM processor and Video core Graphics Processing Unit (GPU). It is the heart of the Raspberry Pi and controls the operations of all the connected devices and handles all the required computations.

HDMI: A High Definition Multimedia Interface can be used for transmitting video or digital audio data to a computer monitor or to digital TV. This HDMI port helps Raspberry Pi to connect its signals to any digital device such as a monitor digital TV or display through an HDMI cable. Those skilled in the art will appreciate that the HDMI port, as well as some of the other ports discussed below, may not be needed to test some devices, including, for example, the consumer electronic device shown in FIGS. 2A, 2B, and 2C.

GPIO ports: General Purpose Input Output ports are available on Raspberry Pi in order to allow the user to interface various I/O devices to Raspberry Pi using Inter-Integrated Circuit (I2C) serial bus and other means. Those skilled in the art will appreciate that the GPIO ports, and I2C, may be used to allow the test fixture controller 160 to communicate with and control the functions of the actuator 180 and the light sensor 190 on the test jig 150.

Audio output: An audio connector is available for connecting audio output devices such as headphones and speakers.

USB ports: This is a common port available for various peripherals such as a mouse, keyboard, or any other I/O device. With the help of a USB port, the system can be expanded by connecting more peripherals.

SD card: An SD card slot is available on Raspberry Pi. An SD card with an operating system installed is required for booting the device.

Ethernet: The ethernet connector can be used to access to a wired network.

Power supply: A micro USB power connector is available onto which a 5V power supply can be connected.

Camera module: Camera Serial Interface (CSI) can be used to connect the Broadcom processor to a camera.

Display: Display Serial Interface (DSI) can be used for connecting an LCD to Raspberry Pi using 15-pin ribbon cables. DSI provides a high-resolution display interface that is specifically used for sending video data.

Those skilled in the art will appreciate the flexibility provided by devices such as the Raspberry Pi. They will also appreciate that not all of the features, interfaces, ports, connectors, or capabilities of the Raspberry Pi are required or used in the test fixture 20 described herein.

The features and operation of the test station 10 and test fixture 20, which includes the test jig 150 and the test fixture controller 160, will be described together.

FIG. 5 is a flow chart illustrating the high level process that may be performed using test station 10 as described herein. Generally described, this process includes identifying and logging a DUT 80 by serial number, associating the DUT 80 with a test fixture of the plurality of test fixtures 20a-d, and causing the test fixture to run a test script in order to reset and test the DUT. The test fixture reports the results of the test to the master controller 30, which logs the result and displays the result on the display for the operator.

The test process 500 is executed on the master controller 30. It begins at step 505 when the master controller launches a test application or script that displays a graphical user interface (GUI) for the test station operator on the display 40. Generally described, the main test application can be coded in Python or other suitable computer language. The main test application launches a GUI for the test station operator and responds to user inputs from the touchscreen, keyboard, mouse, or scanner. The test application is also able to send commands to, and receive data from, the test fixture controllers at each of the test fixture, and to other elements of the test station, such as the web power switch.

The test flow continues at step 510 and displays a message instructing the operator to use the scanner 65 to scan the DUT's serial number. The serial number is then verified to confirm that the unit is recognized by the test station and that it is ready to be tested in this part of the process. The DUT is placed in one of the one or more test fixtures 20a-d that form a part of the test station 10. Those skilled in the art will appreciate that before the DUT can be placed in a test fixture and tested, the test fixture must be provided with a test jig that matches the physical configuration and features of the DUT, and that the software for testing the DUT must be loaded into the test fixture controller. In addition, the master controller must know which test fixture the DUT is being placed in. This can be accomplished by having the master controller indicate to the test station operator which test fixture it should be placed in. Alternatively, the operator may choose a test fixture and indicate the chosen test fixture to the master controller. In either case, the master controller must ensure that the test fixture is compatible with the DUT and that the test fixture controller is loaded with the test software required to test the particular type of DUT.

Those skilled in the art will appreciate that once the operator places the DUT in the test fixture and initiates the test process for that DUT, the operator is free to carry out the same steps with additional devices to be tested. In other words, since the test station 10 is capable of testing multiple electronic devices simultaneously and asynchronously, there is no need to test only one DUT at a time, or, when testing multiple DUTs, to begin testing two or more of the devices at the same time. The test station may be used to test electronic devices as quickly as the operator is able to remove an electronic device from a test fixture, replace it with another one, and use the test station master controller's user interface to initiate the testing of the next electronic device.

At step 515, the main test script opens a connection to the test fixture controller in the appropriate test fixture using an SSH protocol connection.

If, at step 520, the connection is determined to be successful, the process advances to step 525 where the master controller 30 sends a command to the test fixture controller 160 to begin executing the test script. This test script is described more fully in conjunction with FIG. 6. If the connection is not successful at step 520, the process proceeds to step 530 and resets the GUI display.

At step 535, master controller 30 checks to see if the execution of the test script has been completed. If not, it repeats this step until the test script execution is complete or the process is otherwise interrupted or reset.

When the execution of the test script is completed at step 535, the test fixture controller 160 returns data indicating whether the DUT has passed the test. In an exemplary embodiment, the test fixture controller returns an integer value back to main test script running on the master controller. The value of the returned integer indicates whether the DUT passed, failed or that the test was terminated due to any hardware malfunction or software exception. For example, the test fixture controller may return a value of zero if the test was passed successfully, a value greater than zero if the test failed, or a value less than zero if there was a software exception due to a hardware problem.

At step 540, the main script running on the master controller saves a detailed test log that contains any messages the test fixture controller test script posted during execution. The detailed test log can include any information that the operator desires to have regarding the test, such as the DUT's serial number, whether the device was successfully reset, which tests were run, the results of those tests, etc. In other words, the results that are reported by the test fixture and stored by the master controller do not need to be limited to a simple pass/fail type of indication. This data may be stored locally in the master controller or transferred and saved in a remote server (not shown) or in a cloud-based storage system (not shown). Those skilled in the art will appreciate that storing such information may be useful because it allows those doing the testing to track the status of electronic devices that it has tested. If one of the tested devices is subsequently returned to the testing company due to a problem, they will have some data about the earlier testing and performance of the electronic device.

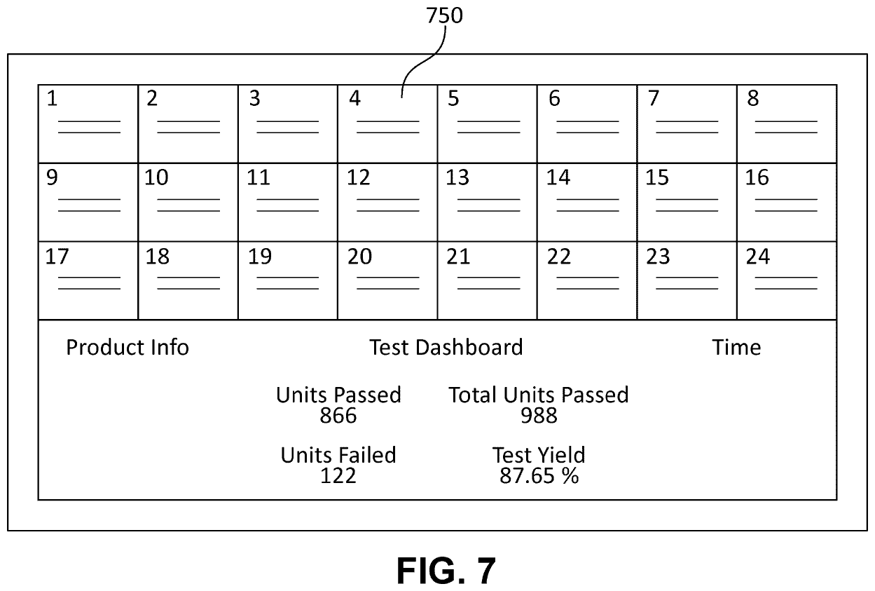

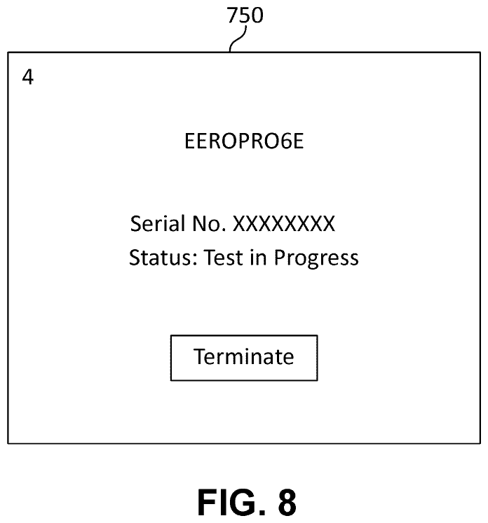

At step 545, the master controller causes the GUI that is displayed on display 40 to be updated with the tests results (as shown in FIGS. 7 and 8). For each electronic device under test, once the testing is complete, the operator will receive an indication whether the electronic device passed or failed the automated test. The master controller's display 40 may provide a pass/fail indication as described further in conjunction with FIGS. 7 and 8.

If the operator sees that the DUT has not passed the automated test, he or she can acknowledge this by a written notation of some sort, a sticker being attached to the electronic device, or simply placing it in a box or area reserved for failed electronic devices.

If the operator sees that the electronic device has passed the automated test, he or she can acknowledge this by a written notation of some sort, a sticker being attached to the electronic device, or simply placing it in a box or area reserved for electronic devices that have passed the test.

At this point, the testing of the electronic device is complete and the test fixture is ready to test another electronic device. Those skilled in the art will appreciate that these steps may be carried out for each test fixture while the other test fixtures are conducting tests of other electronic devices or while other test fixtures are idle.

The test process that is executed by the master controller ends at step 550.

FIG. 6 is a flow chart illustrating a process or set of steps that may be part of an automated test procedure performed by a test fixture 20a-d in order to reset and test a consumer electronic device (DUT 80). The reset and test process illustrated in FIG. 6 can be the automated test procedure discussed above in FIG. 5 in conjunction with step 525. As noted above, each test fixture can execute an automated test independently, simultaneously, and asynchronously of the other test fixtures that are connected to the same master controller 30.

Before discussing the specific steps illustrated in the flow chart of FIG. 6, it is helpful to describe the process and its objectives at a higher level. Generally described, the test script starts by using an API to issue a command to the web power switch to power on the DUT. A 60-second sleep timer is then used to ensure that the DUT has sufficient time to complete its boot up process before the test continues. After the wait time is completed, the light sensor's sampling rate is configured for 120 msec integration time and auto sampling mode. The test script then continually fetches values from the light sensor through the Inter-Integrated Circuit (I2C) serial bus that connects the test fixture controller to the light sensor in the test jig. The script remains in a polling loop until the desired color light detection condition, or the timer loop expiration condition are satisfied.

The color light detection is obtained through a color space conversion algorithm from RGB to HSL (Hue, Saturation, Luma) measurement values. The Hue value (an angle value in range from 0 to 360) represents the color. To detect white light, the W measurement is used along with Saturation and Luma measurements. The following table (Table 1) shows criteria for different color light detection.

TABLE 1
Color Light Detection Criteria

| Color Light | Measurement Name | Criteria |
|---|---|---|
| Red | Hue (H) | H = 0 +/− 10 deg |
| Yellow | Hue (H) | H = 60 +/− 10 deg |
| Blue | Hue (H) | H = 240 +/− 10 deg |
| White | W (White level), | W > 1000, S = 100 +/− 2, |
| | Saturation (S), | L = 100 +/− 2 |
| | Luma (L) | |

After the sampled light values indicate that the status LED is white and that the DUT is powered up, the linear motor is activated using the test fixture controller's GPIO lines that control a solid state relay to drive voltage and reverse polarity to engage and disengage the linear motor. Once the white color light is detected after DUT boots up, the motor is activated to press and hold DUT's reset button until the light turns from white to yellow to red. This indicates that the DUT has entered reset mode. At that point, the motor is deactivated to release reset button and allow unit to complete the process of resetting itself to factory default settings. The DUT will reboot itself once the factory reset is completed. At that point, the test script will check to see if the status LED is white, which indicates that the DUT has booted up, followed by blue, which indicates that the DUT is ready to be set up again.

The flow chart of FIG. 6 illustrates a process or method for carrying out the reset process described above. In the automated test procedure 600 of FIG. 6, the test process begins at step 605 after a DUT is placed in the test jig and connected to Ethernet and power (as shown in FIG. 4) and the test is initiated by an operator via the main controller 30.

At step 610, the test fixture controller applies power to the DUT by communicating with the web power switch and instructing it to turn power on at the port or outlet associated with the test fixture. As shown in FIG. 4, power is delivered to the DUT via a cable plugged into the DUT's USB-C connector 120.

At step 615, the test fixture controller waits for 60 seconds to give the DUT time to boot up.

At step 620, the test fixture controller reads the W-RGB values from the light sensor and, at step 625, determines if the readings from the light sensor indicate that the status LED on the DUT is white. If not, the process enters a loop to continue reading values from the light sensor until the LED turns white or the process times out. If the status LED is white, the process advances to step 630. If not, the process advances to step 635 and determines if the time out has occurred.

If the timer has not timed out, the process returns to step 620 and reads the light sensor values again. If the timer has timed out, the process advances to step 640 and marks the test as having been failed.

At step 630, the test fixture controller activates the linear motor so that the actuator 180 engages and presses the reset button on the bottom surface of the DUT. The button must be pressed long enough for the DUT to enter the factory reset mode, which is indicated by a change in the color of the status LED. Therefore, the process proceeds to step 645 and reads the values from the light sensor. If the values indicate that the status LED has turned yellow at step 650, the process advances to step 655. If not, the process proceeds to step 660 and determines if a time out has occurred. If not, the process returns to step 645 and reads the values from the light sensor again. If the process has timed out, the process advances to step 640 and marks the test as having been failed.

At step 655, the test fixture controller reads the W-RGB values from the light sensor and, at step 665, determines if the readings from the light sensor indicate that the status LED on the DUT is red. If not, the process enters a loop to continue reading values from the light sensor until the LED turns red or the process times out. If the status LED is red, the process advances to step 670. If not, the process advances to step 675 and determines if the time out has occurred. If not, the process returns to step 655 and reads the light sensor values again. If the timer has timed out, the process advances to step 640 and marks the test as having been failed.

At step 670, the process pauses 10 seconds before advancing to step 680, where the test fixture controller causes the linear motor to disengage, thereby releasing the actuator that is pressing the reset button on the DUT.

At this point, the DUT should boot up and, via the status LED, indicate that it is in the factory default mode. To determine if this is the case, the process advances to step 685 and reads the W-RGB values from the light sensor and, at step 690, determines if the readings from the light sensor indicate that the status LED on the DUT is white. If not, the process enters a loop to continue reading values from the light sensor until the LED turns white or the process times out. If the status LED is white, the process advances to step 695. If not, the process advances to step 700 and determines if the time out has occurred. If the process has not timed out, the process returns to step 685 and reads the light sensor values again. If the timer has timed out, the process advances to step 640 and marks the test as having been failed.

At step 695, the process reads the W-RGB values from the light sensor and, at step 705, determines if the readings from the light sensor indicate that the status LED on the DUT is blue. If not, the process enters a loop to continue reading values from the light sensor until the LED turns blue or the process times out. If the status LED is blue, the process advances to step 710. If not, the process advances to step 715 and determines if the time out has occurred. If the process has not timed out, the process returns to step 695 and reads the light sensor values again. If the timer has timed out, the process advances to step 640 and marks the test as having been failed.

If the status LED was blue at step 705, the process advances to step 710 and marks the test as having been passed. The process 600 then ends at step 720.

Those skilled in the art will appreciate that different electronic devices require different reset routines, use different color lights, require different timing, etc. For example, a flashing status LED may represent one state, while a solid status LED represents a different state. Similarly, the reset button may need to be pressed more than once or held for a longer time. All of these variations can be accommodated by changing the test script to sample for different values, cause the linear motor to engage more than once, etc. In other words, the test fixture controller and test jig are flexible enough and may be modified to accommodate a variety of differences in the electronic devices and their manner of operation.

FIGS. 7 and 8 illustrate various aspects of the screens and messages that may be displayed to a test station operator as part of the GUI on the display 40 that forms a part of the test station.

FIG. 7 depicts an exemplary screen display that is controlled by the master controller 30 and presented on display 40. The top part of the screen provides information about each of the test fixtures associated with the test station. This provides the user interface for the test station operator to select a specific test fixture for use or to see its status. Each window provides the operator with information about the status of the test fixture, including, for example, the type of electronic device being tested, the serial number of the electronic device being tested, and the status of the device. For example, the status line might indicate that the test is in progress or that the electronic device has passed or failed a test.

The bottom portion of the screen shown in FIG. 7 can provide summary info associated with the test process. For example, the screen can display the number of devices tested, the number of devices that have passed and failed, and the total yield (i.e., the percentage of tested devices that have passed).

FIG. 8 depicts window 750, which is one of the windows shown in the top portion of the display in FIG. 7. As mentioned above, the purpose of a window is to provide a user interface that facilitates the operator's ability to control and monitor the progress of the automated testing described above. The window for each test fixture can show the serial number of the device under test and the status of the test. It can also provide information about the type of devices the test fixture is set up to test (e.g., EEROPRO6E). The window can also provide controls that can be selected by the operator. For example, the window can include an icon that can be selected to terminate the test. Those skilled in the art will appreciate that the window can be designed to provide virtually any type of information about the test fixture, the electronic device under test, or the test itself. It can also provide the user interface elements that allow the operator to conveniently select the desired operations and enter any required information. As noted above, the operator's manner of interacting with the display will depend on whether the display is a touch screen, or whether a mouse, trackpad, scanner, or other device are provided for data input.

By way of illustration, each window may provide a test fixture number in order to indicate which test fixture is associated with that window. In FIG. 8, the window 750 is associated with test fixture 4.

The window can also provide a start/terminate icon. The operator may touch this icon to initiate the automated test on a test fixture after an electronic device is placed in it as described in FIG. 4. Once the test is running, this field will provide a mechanism by which the operator may terminate the test if there is a need or desire to do so.

The window can include a current test field that indicates the specific test that is being performed by that test fixture at any given point in the process. This can allow the operator to monitor the testing and determine if the automated test is progressing as expected. In order to display status messages, the master controller 30 receives information from the test fixtures 20a-d throughout the testing cycle.

Once the testing is complete, a pass/fail field can display a message that indicates whether the electronic device under test passed or failed the test. A simple “passed” message can be used to indicate that the electronic device under test has passed all of the tests. A more detailed “failed” message can indicate which test or tests the electronic device failed. For example, a message that says “Failed to power up” would indicate that the electronic device failed to power up in the initial portion of the test.

A current count field (not shown) can be used to indicate how many tests have been performed by a test fixture and how many of the electronic devices tested by the test fixture passed or failed the automated test.

Those skilled in the art will appreciate that the automated testing process of FIGS. 5 and 6 and the displays of FIGS. 7 and 8 are provided by way of example only and that many variations are possible. For example, an automated testing process may perform all or fewer of the tests shown here. Alternatively, additional or alternative tests may be performed as part of the testing process depending on the features associated with the consumer electronic devices that are being tested. Similarly, the conditions under which the tests terminate also may vary. For example, automated test procedure 600 arrives at step 640 from one of five steps, namely steps 635, 660, 675, 700, or 715. In order to save time, the test station operator may want the procedure performed by the test fixture to terminate as soon as a DUT fails any test. It is also possible that the test station operator may want the test fixture to run all of the tests even if one or more are failed in order to produce a comprehensive list of the features that do or do not work. Other test outcomes and possible conclusions to be drawn from those outcomes will be known to those skilled in the art. As mentioned above, all of this information can be stored in order to provide information about specific electronic devices, or about trends that may become apparent after testing many electronic devices of the same or similar type. Those skilled in the art will appreciate that there can be many uses for this type of data.

Those skilled in the art will appreciate that the specific tests and sequences discussed in conjunction with the automated test procedure 600 are provided as an illustration and that many variations as possible depending on the features of the consumer electronic devices being tested and the test fixture being employed.

Those skilled in the art will appreciate how the present disclosure and the embodiments described herein provide test fixtures 20, which include test fixture controllers and test jigs, that are capable of testing multiple functions on a consumer electronic device. The components of the test jig 150 can be controlled by a test fixture controller 160 that runs a test script or routine that causes the components of the test jig 150 to provide the desired inputs to electronic devices, and to collect and analyze the outputs from those electronic devices. In the embodiments disclosed herein, the inputs to the electronic devices under test include the button presses from the actuators 180. The outputs from the electronic device under test include the status LED. In light of the foregoing discussion, those skilled in the art will appreciate that a test fixture that has been used to test one model consumer electronic device may be reconfigured to test a different model by replacing the test jig with a new, appropriate test jig, and causing the test fixture controller to execute a test routine compatible with the new test jig and the new model of consumer electronic device.

Although several aspects have been disclosed in the foregoing specification, it is understood by those skilled in the art that many modifications and other aspects will come to mind to which this disclosure pertains, having the benefit of the teaching presented in the foregoing description and associated drawings. It is thus understood that the disclosure is not limited to the specific aspects disclosed hereinabove, and that many modifications and other aspects are intended to be included within the scope of any claims that can recite the disclosed subject matter.

The logical operations, functions, or steps described herein as part of a method, process or routine may be implemented (1) as a sequence of processor-implemented acts, software modules, or portions of code running on a controller or computing system and/or (2) as interconnected machine logic circuits or circuit modules within the controller or computing system. The implementation is a matter of choice dependent on the performance and other requirements of the system. Alternate implementations are included in which operations, functions or steps may not be included or executed at all, may be executed out of order from that shown or discussed, including substantially concurrently or in reverse order, depending on the functionality involved, as would be understood by those reasonably skilled in the art of the present disclosure.

One should note that conditional language, such as, among others, “can,” “could,” “might,” or “may,” unless specifically stated otherwise, or otherwise understood within the context as used, is generally intended to convey that certain aspects include, while other aspects do not include, certain features, elements and/or steps. Thus, such conditional language is not generally intended to imply that features, elements and/or steps are in any way required for one or more particular aspects or that one or more particular aspects necessarily comprise logic for deciding, with or without user input or prompting, whether these features, elements and/or steps are included or are to be performed in any particular aspect.

It should be emphasized that the above-described aspects are merely possible examples of implementations, merely set forth for a clear understanding of the principles of the present disclosure. Any process descriptions or blocks in flow diagrams should be understood as representing modules, segments, or portions of code which comprise one or more executable instructions for implementing specific logical functions or steps in the process, and alternate implementations are included in which functions may not be included or executed at all, can be executed out of order from that shown or discussed, including substantially concurrently or in reverse order, depending on the functionality involved, as would be understood by those reasonably skilled in the art of the present disclosure. Many variations and modifications can be made to the above-described aspect(s) without departing substantially from the spirit and principles of the present disclosure. Further, the scope of the present disclosure is intended to cover any and all combinations and sub-combinations of all elements, features, and aspects discussed above. All such modifications and variations are intended to be included herein within the scope of the present disclosure, and all possible claims to individual aspects or combinations of elements or steps are intended to be supported by the present disclosure.

What is claimed is:

1. A system for simultaneously testing a plurality of electronic devices, comprising:
a plurality of test fixtures, each test fixture of the plurality of test fixtures configured to hold an electronic device under test of a plurality of electronic devices under test, each test fixture of the plurality of test fixtures comprising:
a test fixture controller configured to execute a test routine to test the electronic device under test;
at least one actuator arranged to press at least one button on the electronic device under test;
at least one input/output (I/O) device configured to receive information about the device under test;
a master controller connected to the plurality of test fixtures and operative to control the tests executed by each test fixture of the plurality of test fixtures, the tests executed by the plurality of test fixtures being simultaneous and asynchronous with each other; and
a user interface device connected to the master controller and operative to display a plurality of windows corresponding to the plurality of test fixtures, each window displaying information associated with the testing of one electronic device under test of the plurality of electronic devices under test by the plurality of test fixtures.

2. The system for simultaneously testing a plurality of electronic devices of claim 1, wherein the master controller is further operative to receive from each test fixture test results associated with an electronic device under test of the plurality of electronic devices under test and to store the test results along with a unique identifier associated with each of the electronic devices under test.

3. The system for simultaneously testing a plurality of electronic devices of claim 1, wherein the user interface device comprises a touch screen display.

4. The system for simultaneously testing a plurality of electronic devices of claim 1, wherein the user interface device comprises a display, a keyboard, and a pointing device.

5. The system for simultaneously testing a plurality of electronic devices of claim 1, wherein the master controller provides a test routine to a test fixture in response to first input received via the user interface device and the master controller is operative to cause the test fixture to initiate the test routine in response to second input received via the user interface device.

6. The system for simultaneously testing a plurality of electronic devices of claim 1, wherein the electronic devices under test comprise consumer electronic devices.

7. The system for simultaneously testing a plurality of electronic devices of claim 1, wherein the electronic devices under test comprise Wi-Fi routers.

8. The system for simultaneously testing a plurality of electronic devices of claim 1, wherein the electronic devices under test comprise Wi-Fi access points.

9. The system for simultaneously testing a plurality of electronic devices of claim 1, wherein the electronic devices under test comprise mesh network devices.

10. The system for simultaneously testing a plurality of electronic devices of claim 1, wherein the I/O device is a light sensor capable of determining the status of an LED on the electronic device under test.

11. The system for simultaneously testing a plurality of electronic devices of claim 1, wherein the at least one button pressed by the actuator is a reset button on the electronic device under test.

12. A system for simultaneously testing a plurality of electronic devices, comprising:
a plurality of test fixtures, each of the test fixtures operative to hold an electronic device of a plurality of electronic devices and to execute a test routine to test the electronic device, each of the test fixtures comprising at least one actuator arranged to press at least one button on the electronic device;
a master controller connected to the plurality of test fixtures and operative to control the tests executed independently and asynchronously by each test fixture of the plurality of test fixtures; and
a user interface device connected to the master controller and operative to display a window associated with each of the plurality of test fixtures and to receive instructions and display information associated with the testing of the plurality of electronic devices by the plurality of test fixtures,
wherein the master controller is further operative to receive from each test fixture test results associated with an electronic device of the plurality of electronic devices and to store the test results along with unique identifiers associated with each of the electronic devices.

13. The system for simultaneously testing a plurality of electronic devices of claim 12, wherein the user interface device comprises a touch screen display.

14. The system for simultaneously testing a plurality of electronic devices of claim 12, wherein the user interface device comprises a display, a keyboard, and a pointing device.

15. The system for simultaneously testing a plurality of electronic devices of claim 12, wherein the master controller provides a test routine to a test fixture in response to first input received via the user interface device, and the master controller is operative to cause the test fixture to initiate the test routine in response to second input received via the user interface device.

16. The system for simultaneously testing a plurality of electronic devices of claim 12, wherein the electronic devices comprise Wi-Fi routers.

17. The system for simultaneously testing a plurality of electronic devices of claim 12, wherein the electronic devices comprise Wi-Fi access points.

18. The system for simultaneously testing a plurality of electronic devices of claim 12, wherein the electronic devices comprise mesh network devices.

19. The system for simultaneously testing a plurality of electronic devices of claim 12, wherein the I/O device is a light sensor capable of determining the status of an LED on the electronic device under test.

20. The system for simultaneously testing a plurality of electronic devices of claim 12, wherein the at least one button pressed by the actuator is a reset button on the electronic device under test.
